(19) United States
(12) Patent Application Publication
(10) Pub. No.: US 2004/0238195 A1
(43) Pub. Date: Dec. 2, 2004

(54) Self-mounting EMI shielding gasket for metal shell electronic apparatus connectors

(76) Inventor: Craig Thompson, Pullman, WA (US)

Correspondence Address: CLARK PUNTIGAM, Jensen & Puntigam, P.C., 2033 6th Avenue, #1020, Seattle, WA, 98121, US

(21) Appl. No.: 10/447,775

(22) Filed: May 28, 2003

(51) Int. Cl. H05K 9/00

(52) U.S. Cl. 174/35 GC

(57) ABSTRACT

The EMI shielding gasket includes an opening therein such that the gasket can be fitted around a shell portion of an electrical connector used on the chassis of an electronic apparatus. The gasket opening, which is defined by an interior edge, includes a plurality of teeth-like portions which are adapted and sized to grip a shell portion of the connector, holding the gasket in place on the connector during handling of the connector and/or assembly of the electronic device.

### TECHNICAL FIELD

This invention relates generally to EMI gaskets for metal shell-type electrical signal connectors for electronic apparatus, and more specifically concerns such gaskets which are adapted for retention thereof on the connector, after initial mounting thereof.

### BACKGROUND OF THE INVENTION

Metal shell connectors, including multiple pin connectors, are widely used in electronic apparatus to handle both input and output electrical signals. Such connectors are typically used on the rear and/or front panels to provide electrical connection between the internal circuitry of the electronic apparatus, typically mounted on an electronic circuit board, and external equipment. In some cases, due to the particular configuration of the connector, such as a D-subminiature connector, and the relative position of the circuit board and the panel of the instrument to which the connector is to be mounted, a small space may exist between the connector and the panel. In such cases, a shielding gasket is mounted on the body/shell of the connector between the panel and a facing surface of the connector. Even in the absence of a small space, however, a gasket is often used between the connector and the panel. In general, such shielding gaskets are well known and are available from a variety of manufacturers. The gaskets have various features, such as providing an environmental seal, particularly against moisture, and an EMI (electromagnetic interference) shielding capability.

In many cases, the EMI gasket is simply positioned on the connector, with the adjacent end of the connector being inserted through an opening in the front panel, so that the connector is accessible to a connecting cable. However, such gaskets do on occasion fall off the connector during the assembly process of the apparatus or during other handling of the connector. The loss of the EMI gasket will typically have a detrimental effect on the operation of the device, from an EMI standpoint. Some manufacturers attempt to remedy this by use of adhesives or by use of a compression-fit with a groove in the connector or the chassis plate of the apparatus. Screws can also be used to hold the gasket in place. However, these attempts add expense and/or time to the assembly process, and may still not completely solve the problem.

Accordingly, a simple but reliable arrangement for maintaining a shielding gasket in position on a connector during assembly operations would be desirable.

### SUMMARY OF THE INVENTION

Accordingly, the present invention is a shielding gasket for use with metal shell electrical connectors used with an electronic apparatus, the connectors providing electrical signal connection to and from the electronic apparatus, comprising: a gasket member having an opening therein adapted so that the gasket member fits around a shell portion of the electrical connector, the gasket member being further adapted to fit between a facing surface of the connector and an interior surface of a chassis panel of the electronic apparatus, wherein the opening of the gasket member is defined by an interior edge having at least one edge portion therealong which is configured and arranged to grip the connector shell portion sufficiently to hold the gasket member in place on the connector during handling of the connector.

### BRIEF DESCRIPTION OF THE DRAWINGS

FIG. 1 is an exploded view showing a shielding gasket of the present invention, in relative position to an electrical connector on which it is mounted and an electronic apparatus chassis to which the connector is mounted.

FIG. 2 is front view of the shielding gasket of the present invention.

FIG. 3 is a side elevational view of the gasket of FIG. 2.

### BEST MODE FOR CARRYING OUT THE INVENTION

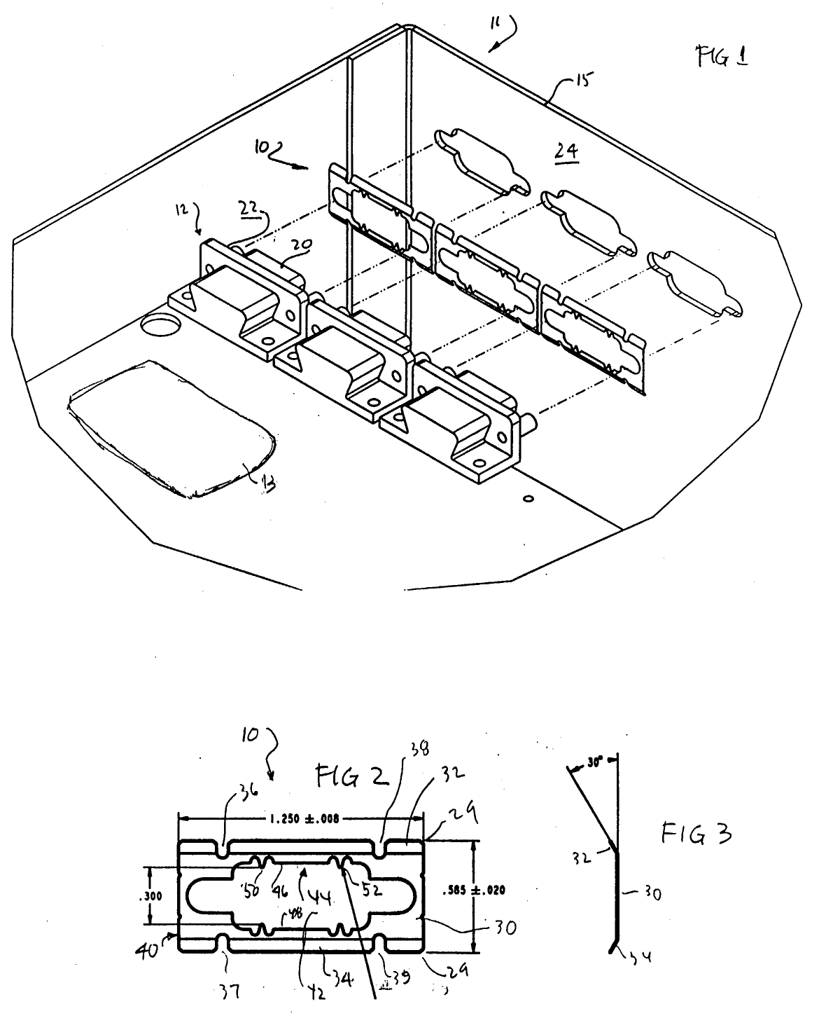

FIG. 1 shows the shielding gasket 10 of the present invention in a structural application, specifically, a three-connector arrangement for an electronic apparatus (shown partially at 11). Fewer or more connectors may be present in a particular application. For example, an electronic apparatus may include an electrical connector member 12 (typically, but not necessarily, multiple pin) for electrical signal connection to the electronic circuitry 13 in the apparatus. One end of connector 12 extends through an opening in chassis plate 15 (usually the front or rear panel).

An external cable connector (not shown) will mate with the apparatus connector 12 and will carry the electrical signals produced by the device to another piece of equipment. The electronic apparatus 11 can be a wide variety of devices. One field of use, for instance, includes electronic equipment for the monitoring and control of electric power, such as protective relays. This is only one example, however, of possible electronic devices which use electrical pin connectors. The connector 12 may vary widely in configuration and arrangement, and of course the number of pins may vary.

The shielding gasket 10 fits around or over a shell portion 20 of the connector 12 between a facing portion 22 of the connector and an internal surface 24 of a chassis panel portion of an electronic device. The gasket 10 has the physical characteristics to accomplish the desired result of EMI protection. The materials used in gasket 10 are similar to that used in other known shielding gaskets. In the particular embodiment shown, the gasket 10 is stainless steel, approximately 0.005 inches thick. Copper is another possibility. One configuration used for a particular connector is shown in FIGS. 2 and 3. The connector is a D-subminiature connector which is a right-angled connector mounted to extend between a circuit board 13 in the apparatus and the front or rear panel 15 of an apparatus.

However, as indicated above, the shielding gasket of the present invention can be used with a wide variety of connector configurations and arrangements. A D-subminiature connector is simply one possible connector.

Gasket 10 of FIG. 1 is shown in more detail in FIGS. 2 and 3. Gasket 10 is rectangular in general configuration, approximately 1.250 inches long by 0.585 inches wide and 0.005 inches thick. The corners 29-29 of gasket 10 are chamfered. The gasket has a longitudinal center portion 30 and two opposing longitudinal edge portions 32 and 34. The longitudinal center portion 30 is approximately 0.45 inches wide, with the edge portions 32, 34 each being approximately 0.07 inches wide. Center portion 30 is substantially flat, while edge portions 32 and 34 are also flat, but are angled away from center portion 30 at an angle of approximately 30°, as shown in FIG. 3. This angle, however, can vary. This structural arrangement aids in the contact with the front panel, as shown in FIG. 1.

Located in the longitudinal edge portions 32, 34, respectively, are two slot openings 36, 38 and 37, 39 extending inwardly from peripheral edge 40 of gasket 10 a distance slightly greater than the width of the edge portions 32 and 34. In the embodiment shown, the slot openings in longitudinal edge portion 32 oppose the slot openings in the other longitudinal edge portion 34. The surface of each slot at the bottom thereof is curved in the embodiment shown, in order to provide multiple contact points for EMI shielding of higher frequency energy.

Center portion 30 of gasket 10 includes an opening 42 which has a peripheral edge 44. Peripheral edge 44 has a shape adapted to substantially conform to the cross-section of the shell portion 20 of connector 12 (FIG. 1). In longitudinal portions 46 and 48, respectively, of peripheral edge 44 are located protrusions 50 and 52 which define relatively sharp barbed/teeth-like pointed elements. In the embodiment shown, there are thus a total of four barbed elements, with two elements extending from each longitudinal portion 46 and 48, directly opposing and extending toward each other. In the embodiment shown, the individual barbed members are designed to produce an interference fit between shell portion 20 of the connector and the gasket 10.

It should be understood, however, that different teeth arrangements could be used, including a different number of teeth elements and different locations; however, the teeth elements must be configured and arranged such that the gasket can grab or have an interference fit with the surface of the shell portion of the connector, such that the gasket will remain in place on the connector after it has been once positioned thereon.

In use, shielding gasket 10 will be positioned onto the shell portion of the connector, forced into an interference fit, or a fit where the barbed elements of the shield grab or bite into the surface of the shell portion of the connector. In either case, however, the shield is mounted on the connector such that it will not readily come off the connector and be lost during assembly operations or other handling of the connector. It thus basically maintains its place on the connector during transport or handling; the force required to remove the shielding gasket is sufficient to ensure that it will remain effectively in position on the connector.

Hence, the present invention is a shield structure which has a stand-alone capability of maintaining its position firmly in place on a connector shell, such as for instance a D-miniature connector. This is accomplished without the use of extraneous devices such as screws or other holding means such as adhesives, nor does it require any particular modification, such as grooves, in the connector surfaces. Thus, there is no increase in the expense or time of the assembly operation, while providing a significant benefit to the process and the final product.

Although a preferred embodiment of the invention has been disclosed for purposes of illustration, it should be understood that various changes, modifications and substitutions could be incorporated in the embodiment without departing from the spirit of the invention which is defined by the claims which follow:

What is claimed is:

1. A shielding gasket for use with and metal shell electrical connectors assembly comprising:
a connector adapted for providing electric signal connection to and from an electronic apparatus, said connector having a smooth metal shell portion; and
a gasket member having an opening therein adapted so that the gasket member fits around the smooth metal shell portion of the electrical connector, the gasket member further adapted to fit between a facing surface of the connector and an interior surface of a chassis panel of the electronic apparatus, wherein the opening of the gasket member is defined by an interior edge having at least one edge portion therealong having a sharp element configured and arranged to bite into the smooth connector shell portion sufficiently to hold the gasket member in place on the connector during handling of the connector.

2. An article of claim 1, wherein said interior edge further comprises a plurality of edge portions positioned along said interior edge.

3. An article of claim 2, wherein all of said edge portions further comprise a sharp element.

4. An article of claim 1, wherein the gasket member is stainless steel.

5. An article of claim 1, wherein the gasket member is copper.

6. An article of claim 1, wherein said interior edge further comprises at least two opposing edge portions along said interior edge, the two opposing edge portions, respectively, being located on opposite sides of said opening, thereby opposing each other.

7. An article of claim 1, wherein the gasket member includes a gasket central longitudinal portion and two gasket longitudinal edge portions, the gasket longitudinal edge portions both being positioned at an angle relative to the central longitudinal portion.

8. An article of claim 6, wherein at least one of said opposing edge portions further comprises a sharp element.

9. An article of claim 1, wherein said sharp element is a sharp point.

10. An article of claim 1, wherein said sharp element is a tooth.

11. An article of claim 1, wherein said sharp element is a barbed element.

12. A shielding gasket for use with metal shell electrical connectors used with an electronic apparatus, the connectors providing electrical signal connection to and from the electronic apparatus, comprising:
a gasket member having an opening therein adapted so that the gasket member fits around a shell portion of the electrical connector, the gasket member further adapted to fit between a facing surface of the connector and an interior surface of a chassis panel of the electronic apparatus, wherein the opening of the gasket member is defined by an interior edge having at least one edge portion therealong having a sharp element configured and arranged to bite into the connector shell portion sufficiently to hold the gasket member in place on the connector during handling of the connector, wherein each side of the base of the sharp element is situated below and spaced from the interior edge portion which defines the opening of the gasket member and the point of the sharp element is situated above the interior edge portion which defines the opening of the gasket member.

13. A shielding gasket for use with metal shell electrical connectors used with an electronic apparatus, the connectors providing electrical signal connection to and from the electronic apparatus, comprising:
a gasket member having an opening therein adapted so that the gasket member fits around a shell portion of the electrical connector, the gasket member further adapted to fit between a facing surface of the connector and an interior surface of a chassis panel of the electronic apparatus, wherein the opening of the gasket member is defined by an interior edge having at least one edge portion therealong having a sharp element configured and arranged to bite into the connector shell portion sufficiently to hold the gasket member in place on the connector during handling of the connector, wherein said gasket member further includes a gasket central longitudinal portion and two gasket longitudinal edge portions, the gasket longitudinal edge portions both being positioned at an angle relative to the central longitudinal portion.
